(19) United States
(12) Patent Application Publication
(10) Pub. No.: US 2026/0066200 A1
(43) Pub. Date: Mar. 5, 2026

(54) PNEUMATICALLY-CONTROLLED RF SWITCH

(71) Applicants: Sung-Min Sohn, Chandler, AZ (US); Chavalchart Herabut, Phoenix, AZ (US)

(72) Inventors: Sung-Min Sohn, Chandler, AZ (US); Chavalchart Herabut, Phoenix, AZ (US)

(21) Appl. No.: 19/313,345

(22) Filed: Aug. 28, 2025

Related U.S. Application Data
(60) Provisional application No. 63/689,345, filed on Aug. 30, 2024.
(60) Provisional application No. 63/778,289, filed on Mar. 26, 2025.

(51) Int. Cl. H01H 35/24; G01R 33/36; H01H 1/36; H01H 3/02; H01H 9/02

(52) U.S. Cl. CPC H01H 35/242; G01R 33/3628; H01H 1/365; H01H 3/0206; H01H 3/0213; H01H 9/0271

(57) ABSTRACT

A pneumatically controlled RF switch configured to toggle an RF circuit between different states by opening or closing electrical contacts. The RF switch provides a reliable binary method for high power non-magnetic switching without introducing electrical noise or interference. The RF switch is configured to maintain optimized RF conditions and facilitate fine-tuning of RF frequency, impedance matching, and RF decoupling.

### CROSS-REFERENCE TO RELATED APPLICATIONS

This application is a non-provisional of and claims the benefit of U.S. Provisional Patent Application No. 63/689,345, filed on Aug. 30, 2024 and U.S. Provisional Patent Application No. 63/778,289, filed on Mar. 26, 2025, the entire contents of each application are incorporated herein by reference.

### BACKGROUND

Radiofrequency (RF) switches are important components in various RF circuits and systems, enabling precise control of signal flow across multiple pathways. Key performance parameters include insertion loss, which quantifies the power lost when the switch is in the ON state, influencing the system's noise vulnerability. Isolation measures the effectiveness of the switch in preventing RF signal leakage during the OFF state. Leakage can introduce unwanted signals into circuits, potentially causing interference and leading to circuit damage if excessive. The insertion loss and RF leakage can significantly impact the signal-to-noise ratio (SNR). Switching speed is another important parameter, indicating how rapidly the switch can change states of activation.

One of the most commonly and widely used RF switching components is the positive-intrinsic-negative (PIN) diode as a single-pole single-throw (SPST) switch. When a DC forward-biased voltage is applied across the PIN diode, the diode turns on and allows RF signals to pass through. When the diode is subjected to reverse bias, RF signals are blocked. This property allows the PIN diode to switch via DC biasing, making it advantageous for applications requiring electronic control. However, due to the relatively high resistance of the internal PIN diode's structure compared to conductors like copper, PIN diodes exhibit a high insertion loss, which can degrade signal quality due to power loss. PIN Diodes also require multiple low-impedance capacitors or DC blocks to prevent the DC biasing signals from entering the RF source or load. These components are typically positioned on the main signal line, further introducing loss. High-impedance inductors or RF chokes are also required to stop RF signals from entering the DC biasing circuits. However, chokes still produce some RF leakage, causing unwanted RF coupling. Additional filters are often needed to eliminate RF leakage. Both insertion loss and RF leakage are nonlinear with respect to frequency, biasing conditions, and RF power levels. All these effects should be considered for SNR-prioritized applications, such as magnetic resonance imaging (MRI), which provides a non-invasive and highly detailed view of the human body. By using magnetic fields and radiofrequency (RF) waves, MRI produces precise images of organs, tissues, and anatomical structures with exceptional contrast and resolution.

Recently, micro-electromechanical systems (MEMs) switch designs have been introduced in MRI, offering lower insertion loss, higher linearity, and improved isolation with lower RF leakage. However, both PIN and MEMs switches require electrical driver circuitry and high-voltage DC biasing, delivered through long cables from outside the RF-shielded MRI room. This setup often introduces significant RF noise on MR images (e.g., zipper artifact), generates eddy currents, and causes high-power RF transmit coupling. These factors also introduce electrical hazards associated with all electric components for MRI and must comply with the international electrotechnical commission (IEC) standard 60601, ensuring that the RF coil (i.e., MRI antenna) surface temperature does not exceed 43° C. during MRI scanning. Thus, the use of electrically driven RF switches in MRI remains challenging in minimizing their negative impact on image quality (i.e., SNR) and safety.

Accordingly, an RF switch that provides low-loss and high isolation would be desirable to overcome the above limitations of PIN diodes and MEMS switches.

### SUMMARY

In one embodiment, the present disclosure provides a radio-frequency (RF) switch comprising a housing and a block. The housing defines an interior volume and includes a first end and a second end, the first end including a port in fluid communication with an air pressure source, the second end including a plurality of pads in electrical communication with components on a circuit board. The block is positioned within the housing and extends a width of an interior surface of the housing, the block is configured to move along an axis, the block includes a lower portion having an electrically conductive material. The RF switch is activated when the lower portion of the block moves along the axis to be in contact with the plurality of pads due to pressurization of the interior volume, and the RF switch is deactivated when the lower portion of the block moves along the axis to not be in contact with the plurality of pads due to depressurization of the interior volume.

In some embodiments, the RF switch further comprises a first leg and a second leg extending from the plurality of pads into the interior volume of the housing, and wherein the lower portion of the block removably contacts the first leg and the second leg.

In some embodiments, the first leg and the second leg include an electrically conductive material.

In another embodiment, the present disclosure provides a system comprising an RF coil or a circuit and a plurality of pneumatically switchable circuit components in selective electrical communication with the RF coil or the circuit, the plurality of pneumatically switchable circuit components in communication with an air pressure source or a vacuum source to adjust one of a capacitance, an inductance, or a resistance of the pneumatically switchable circuit components.

In some embodiments, the plurality of pneumatically switchable circuit components includes one or more of a capacitor, an inductor, a resistor, and a signal pathway switch.

In some embodiments, the plurality of pneumatically switchable circuit components are oriented in parallel with a plurality of fixed circuit components.

In some embodiments, one of the plurality of pneumatically switchable circuit components comprises a housing in communication with the air pressure source or the vacuum source, a first connector coupled to the housing and configured to move within the housing, and a second connector electrically coupled to the RF coil or the circuit, the second connector defining a recess configured to selectively receive the first connector, wherein the first connector is received within the recess when a sufficient amount of air pressure is applied to the housing, and wherein the first connector is not in contact with the second connector when a vacuum is applied to the housing.

In some embodiments, one of the pneumatically switchable circuit components is activated when the first connector is engaged with the second connector thereby generating an electrical connection.

In some embodiments, one of the pneumatically switchable circuit components is deactivated when the first connector is disengaged with the second connector.

In some embodiments, the plurality of pneumatically switchable circuit components are configured to control a resonating property of the RF coil.

In some embodiments, the resonating property is frequency.

In another embodiment, the present disclosure provides a method comprising positioning a pneumatically-controlled switchable circuit in electrical communication with a fixed circuit component, and controlling the pneumatically-controlled switchable circuit to optimize radio-frequency (RF) conditions of a RF coil by applying air pressure or vacuum to the pneumatically-controlled switchable circuit.

In some embodiment, the RF conditions are frequency, impedance matching, and RF decoupling.

In some embodiments, the RF coil is in a magnetic resonance imaging device.

In some embodiments, the method includes controlling the pneumatically-controlled switchable circuit in real-time to optimize the RF conditions of the RF coil during an MRI procedure.

In yet another embodiment, the present disclosure provides a system for magnetic resonance imaging (MRI) or magnetic resonance spectroscopy. The system comprises a radiofrequency (RF) coil and a pneumatic control system electrically coupled to an MRI scanner. The pneumatic control system includes a plurality of pneumatically switchable circuit components in selective electrical communication with the RF coil, the plurality of pneumatically switchable circuit components in communication with an air pressure source or a vacuum source to optimize RF conditions of the RF coil. The pneumatic control system is configured to adjust one of the RF conditions of the RF coil by adjusting one or more of the plurality of pneumatically switchable circuit components to match a target nucleus being measured before a pulse sequence for each nucleus based on a gating signal received from the MRI scanner.

In some embodiments, one of the plurality of pneumatically switchable circuit components is a capacitor.

In some embodiments, one of the RF conditions is resonant frequency.

In some embodiments, the pneumatic control system is configured to adjust one of the RF conditions of the RF coil in real-time.

In some embodiments, the pneumatic control system is configured to adjust one of the RF conditions based on a predetermined pulse sequence for each nucleus.

Other aspects of the disclosure will become apparent by consideration of the detailed description and accompanying drawings.

### BRIEF DESCRIPTION OF THE DRAWINGS

The features and advantages of the present disclosure, and the manner of attaining them, will become more apparent and the present disclosure will be better understood by reference to the description of the present disclosure taken in conjunction with the accompanying drawings, wherein:

FIG. 1 is a RF switch according to an embodiment of the present disclosure.

FIG. 2 is a photomicrograph of an enlarged portion of a prototype RF switch illustrated in FIG. 1.

FIG. 3 is (A) a photograph of the prototype RF switch illustrated in FIG. 1; (B) a photograph of component arrangement for a fabricated PIN diode; (C) a schematic of the RF switch in (A); and (D) a schematic of the PIN diode in (B).

FIG. 4 is (A) a photograph of a fabricated RF switch array; (B) a photograph of a fabricated PIN diode array; (C) a schematic of the RF switch array; and (D) a schematic of the PIN diode array.

FIG. 5A is (A) a photograph of an L-Matching and tuning network of a basic circuit for MRI coils; (B) a schematic of the L-matching and tuning network in (A); (C) a photograph of an RF switch-based circuit; and (D) a photograph of a PIN diode-based circuit.

FIG. 5B is (E) a schematic of the RF switch-based circuit in FIG. 5A (at C); (F) a schematic of the PN diode-based circuit in FIG. 5A (at D); and (G) an experimental setup for comparing matching network performance.

FIG. 6 is a block diagram of an air pressure source according to an embodiment of the present disclosure.

FIG. 7 illustrates measured oscilloscope signals of (A) activation of the OFF state (top) and ON state (center) with electrical and mechanical latency timing of T_{LF} and T_{LR}, as well as RF pulse (bottom); (B) switching time of the rising (T_{R}) and falling (T_{F}) time; and (C) potential unstable switching behavior.

FIG. 8 illustrates measured S21 of both the RF switch and PIN diode using VNA for (A) isolation while the switches are deactivated and (B) insertion loss when the switches are activated.

FIG. 9 illustrates a temperature comparison of the RF switch and PIN diode in different states: (A) RF switch in the ON state; (B) RF switch in the OFF state; (C) PIN diode in the ON state; and (D) PIN diode in the OFF state.

FIG. 10 illustrates measured S21 for all 16 switching combinations of (A) the RF switch array and (B) the PIN diode array.

FIG. 11 is a Smith chart displaying input impedance across all switching combinations: (A) the impedance without a load and (B) with a load using both the RF switch and the PIN diode.

FIG. 12 is a chart showing the 16 switching configurations displayed as 0000 to 1111.

FIG. 13 illustrates (a) a diagram of a single-tune coil, (b) an RF coil according to an embodiment of the present disclosure, e.g., RF coil with RF switch, (c) a conceptual diagram of a pneumatically switchable capacitor according to an embodiment of the present disclosure when deactivated, and (d) activated by the air pressure.

FIG. 14 illustrates (a) a single-tuned RF coil for ²H, (b) a single-tuned RF coil for ¹H, and (c) RF coil with RF switch.

FIG. 15 is a schematic diagram of an air control system circuit connected to the RF switch.

FIG. 16 is a perspective view of a 3D design of a phantom container (left) and a diagram of the concentration of in percentage D₂O in each compartment diluted in H₂O (right).

FIG. 17 is an S₁₁ plot of at 61 MHz and 400 MHz comparing each coil from bench testing.

FIG. 18 illustrates an imaging experiment setup in the control room showing the air control station and coil setup on an animal bed on the MRI scanner inside the scan room.

FIG. 19 illustrates an MRI image result comparing the single-tuned coil and the AeroCoil for T2 weighted and FLASHDCE sequence at 400 MHZ (left) and 61 MHz (right).

FIG. 20 illustrates regions of interest selection of the result images for measuring noise STD (left) and for measuring signal intensity (right).

FIG. 21 graphically illustrates SNR of each ²H concentration comparing RF coil with RF switch and the single-tuned coil for both imaging sequences at 61 MHz for D₂O imaging (left) and 400 MHz for H₂O imaging (right).

Those of ordinary skill in the art will understand that the devices and methods specifically described herein and illustrated in the accompanying drawings are non-limiting exemplary embodiments and that the scope of the various embodiments of the present disclosure is defined solely by the claims. The features illustrated or described in connection with one exemplary embodiment may be combined with the features of other embodiments. Such modifications and variations are intended to be included within the scope of the present disclosure.

### DETAILED DESCRIPTION

Before any implementations are explained in detail, it is to be understood that the implementations are not limited in application to the details of the configurations and arrangements of components set forth in the following description or illustrated in the accompanying drawings. The implementations are capable of being practiced or of being carried out in various ways. Also, it is to be understood that the phraseology and terminology used herein are for the purpose of description and should not be regarded as limiting.

Unless otherwise defined, all technical and scientific terms used herein have the same meaning as commonly understood by one of ordinary skill in the art. In case of conflict, the present document, including definitions, will control. The materials, methods, and examples disclosed herein are illustrative only and not intended to be limiting. Methods and materials similar or equivalent to those described herein can be used in practice or testing of the disclosed invention. All publications, patent applications, patents and other references mentioned herein are incorporated by reference in their entirety.

The terms “comprise(s),” “include(s),” “having,” “has,” “can,” “contain(s),” and variants thereof, as used herein, are intended to be open-ended transitional phrases, terms, or words that do not preclude the possibility of additional acts or structures. The present disclosure also contemplates other embodiments “comprising,” “consisting of” and “consisting essentially of,” the embodiments or elements presented herein, whether explicitly set forth or not.

Unless specified or limited otherwise, the terms “mounted,” “connected,” “supported,” and “coupled” and variations thereof are used broadly and encompass both direct and indirect mountings, connections, supports, and couplings.

Unless the context of their usage unambiguously indicates otherwise, the articles “a,” “an,” and “the” should not be interpreted as meaning “one” or “only one.” Rather these articles should be interpreted as meaning “at least one” or “one or more.” Likewise, when the terms “the” or “said” are used to refer to a noun previously introduced by the indefinite article “a” or “an,” “the” and “said” mean “at least one” or “one or more” unless the usage unambiguously indicates otherwise.

For the recitation of numeric ranges herein, each intervening number therebetween with the same degree of precision is explicitly contemplated. For example, for the range of 6-9, the numbers 7 and 8 are contemplated in addition to 6 and 9, and for the range 6.0-7.0, the number 6.0, 6.1, 6.2, 6.3, 6.4, 6.5, 6.6, 6.7, 6.8, 6.9, and 7.0 are contemplated, and for the range 1.5-2, the numbers 1.5, 1.6, 1.7, 1.8, 1.9, and 2 are contemplated.

Relative terminology, such as, for example, “about,” “approximately,” “substantially,” etc., used in connection with a quantity or condition would be understood by those of ordinary skill to be inclusive of the stated value and has the meaning dictated by the context (e.g., the term includes at least the degree of error associated with the measurement accuracy, tolerances [e.g., manufacturing, assembly, use, etc.] associated with the particular value, etc.). To illustrate, the term “about” used in connection with a quantity is inclusive of the stated value and has the meaning dictated by the context (for example, it includes at least the degree of error associated with the measurement of the particular quantity). The term “about” should also be considered as disclosing the range defined by the absolute values of the two endpoints. For example, the expression “from about 2 to about 4” also discloses the range “from 2 to 4.” The term “about” may refer to plus or minus 10% of the indicated number. For example, “about 10%” may indicate a range of 9% to 11%, and “about 1” may mean from 0.9-1.1. Other meanings of “about” may be apparent from the context, such as rounding off, so, for example “about 1” may also mean from 0.5 to 1.4.

The present disclosure provides a pneumatically controlled RF switch that provides low-loss and high isolation. The pneumatically controlled RF switch provides a non-magnetic property with minimal electrical components. In some aspects, the RF switch is a self-temperature-regulated switch, particularly for high-power RF circuits.

As described below, in some embodiments, the RF switch provides optimization for switching-based RF coils in a magnetic resonance (MRI) system, such as frequency tuning and impedance matching, that occurs before imaging and has no strict timing constraints. The RF switch disclosed has applications in RF ablation, hyperthermia, interventional systems with MRI, and other medical devices requiring RF circuit controls. The RF switch can also be utilized in general applications for circuit components including capacitors, inductors, and resistors as well as simple signal path switches.

The pneumatically controlled RF switch is configured to toggle an RF circuit between different states by opening or closing electrical contacts. This RF switch provides a reliable binary method for high power non-magnetic switching without introducing electrical noise or interference. The pneumatically controlled capacitor is configured to adjust the capacitance of RF circuits. This allows precise control of the capacitance for finding the optimized RF conditions at the desired frequency. The RF coil is configured to maintain optimized RF conditions and facilitate fine-tuning of RF frequency, impedance matching, and RF decoupling.

The present disclosure provides a system that leverages the following principles and advantages: 1) Noise reduction: pneumatic control eliminates electrical noise that is typically associated with DC bias's direct electrical contact to main RF signal lines; 2) Stability, safety and reliability: pneumatic components are less susceptible to electromagnetic interference, enhancing the stability and reliability of the RF control system even in high RF power transmission. By replacing electrical wires with air conduits, the system reduces electrical hazards. Air conduits can be placed anywhere without affecting the local magnetic field (B1). This approach surpasses the limitations of PIN diode control, MEMs, and manual adjustment; 3) Integration and expansion: the central pneumatic control unit of the system orchestrates the operation of RF switch and RF switch arrays, which can be synchronized with MRI and magnetic resonance spectroscopy (MRS) procedures. The air control unit is positioned remote from the magnet, allowing for versatile connectivity options such as wireless control and powerful computing for fully automated RF coil tuning, matching, and decoupling. Unlike fast RF switching, such as a Tx/Rx switch, which necessitates a range of nanoseconds to microseconds, capacitive switching for RF coil optimization is typically performed before commencing an imaging session and does not have a strict switching time limit.

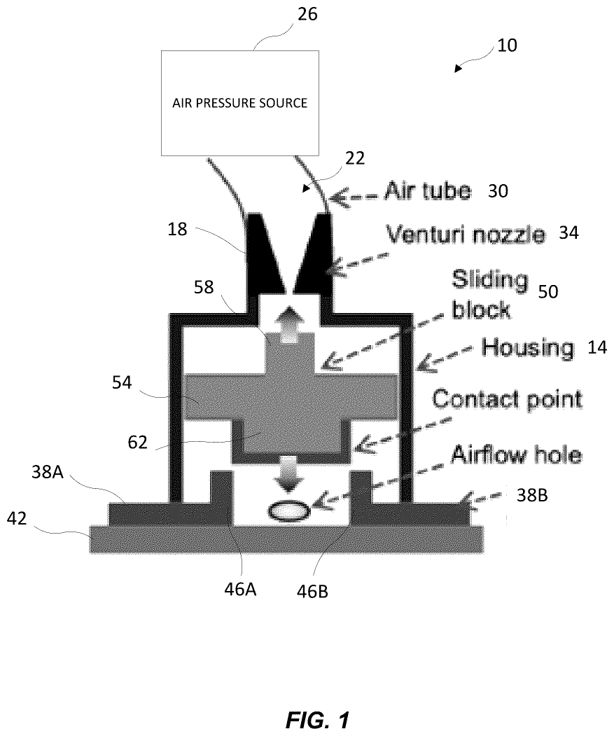

FIG. 1 illustrates an RF switch 10 according to an embodiment of the present disclosure. The RF switch 10 includes a housing 14 defining an interior volume therein. The housing 14 includes a port 18 extending from an upper end of the housing 14. The port 18 includes an opening 22 in fluid communication with an air pressure source 26 through a conduit 30. The port 18 includes an internal surface having a diameter that decreases from an upper end to a lower end thereby defining a venturi nozzle 34. The housing 14 includes a pair of pads 38A, 38B at a lower end that are in electrical communication with electrical components on a circuit board 42. Each pad 38A, 38B in the pair of pads 38 includes a leg 46A, 46B extending into the interior volume of the housing 14. In some aspects, the pads 38A, 38B are soldered to the circuit board 42 and comprise an electrically conductive material (e.g., copper).

The housing 14 includes a block 50 positioned in the interior volume and is configured to slide upwards and downwards along an axis A in response to changes in air pressure supplied by the air pressure source 26. The block 50 includes a body 54 extending a width of an interior surface of the housing 14 thereby separating the interior volume into an upper chamber and a lower chamber. The upper chamber is in fluid communication with the air pressure source 26 through the port 18 and the conduit 30. The block 50 includes an upper portion 58 extending from an upper surface of the body 54 and a lower portion 62 extending from a lower surface of the body 54. The lower portion 62 has a width less than the width of the body 54 and is sized to fit within a width defined by the legs 46A, 46B. The lower portion 62 includes an electrically conductive material (e.g., copper). The upper portion 58 has a width less than the width of the body 54 and is sized to fit within a width defined by the port 18.

When the upper chamber of the interior volume of the housing 14 is pressurized, the block 50 is pushed downward along axis A to electrically connect the lower portion 62 of the block 50 with the legs 46A, 46B. This electrical connection allows electrical current to flow thereby activating the RF switch 10. When the upper chamber of the interior volume of the housing 14 is depressurized or under vacuum, the block 50 moves upward along axis A to no longer be in contact with the legs 46A, 46B. When the block 50 is no longer in contact with the legs 46A, 46B, the electrical circuit is disconnected thereby deactivating the RF switch 10.

### Example—RF Switch

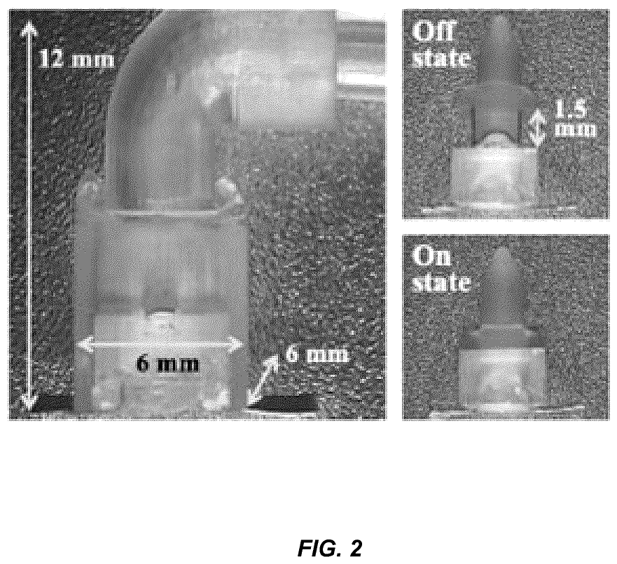

With reference to FIG. 2, a prototype of the RF switch 10 is shown. An example RF switch 10 was designed to reduce minimal electric resistance and minimize parasitic reaction, ensuring efficient optimal performance. The structural components were fabricated using a resin 3D printer (e.g., Photon Mono M5s Pro, Anycubic, China) with an XY resolution of 16.8×24.8 mm and the electrically conductive parts were manually formed by folding a 0.2 mm thin pure copper sheet. The housing has dimensions of 6 mm×6 mm×12 mm, with internal contact points measuring 2 mm×1.5 mm on both sides. The measured weight of the sliding block was 63.1 mg, and it functions as a plunger driven by airflow. A mini air pump (e.g., Ultra Silent Mini 12V DC Air Pump, Jadeshay, China) provided an airflow of 2˜3.2 liters per minute (LPM), generating a vacuum with a pressure below 420 millimeters per mercury (mmHg), which was used to operate the RF switch. To maximize airflow control and efficiency, the top opening of the housing was sealed as a chamber with a Venturi nozzle to increase airflow velocity, while small holes in the housing were positioned below the chamber to enhance the pressure difference between the interior and exterior of the chamber. The performance of the RF switch was evaluated by comparing it with a PIN diode switch through the different experiments described below.

### Evaluation of a Single RF Switch

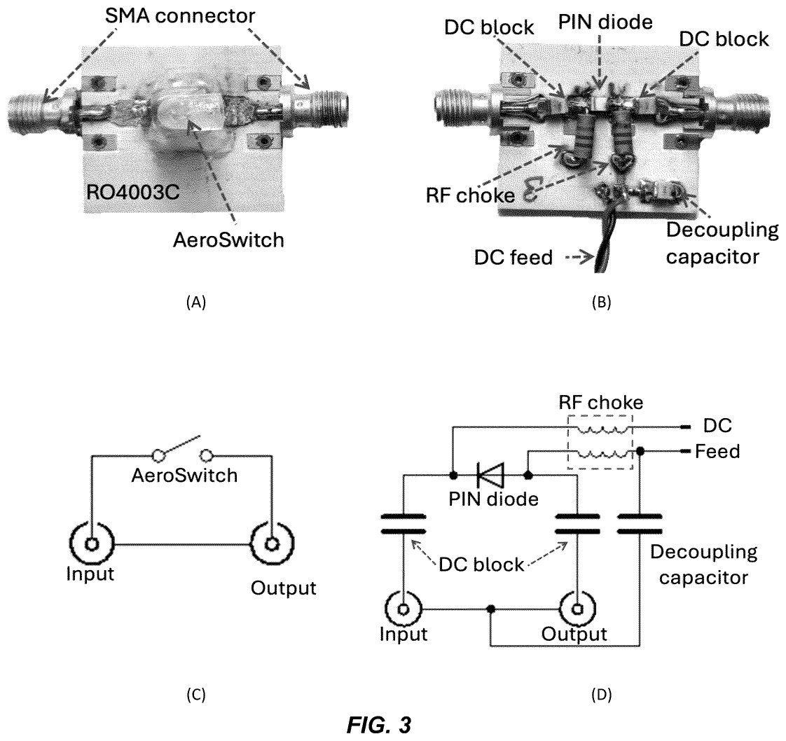

First, the RF switch 10 was soldered onto a small PCB milled using substrate material (e.g., RO4003C, Rogers Corporation, USA) as shown in FIG. 3 (at A, C). Two SMA connectors were connected to each leg of the RF switch 10. The back side of the PCB was ground filled for a 50 Ω transmission line. Similarly, a low-loss, high-power, non-magnetic PIN diode (e.g., MA4P7470F-1072T, MACOM Technology Solutions Holdings, Inc., USA) was soldered onto an identical PCB of the same size, including the bias circuit, as shown in FIG. 3 (at B). The DC feeds into the PIN diode through an RF choke of 330 nH inductor (e.g., IM02EBR33K, Vishay Intertechnology Inc., USA) and returns to the ground through another choke as shown in FIG. 3 (at D). A pair of 560 pF capacitors (DKD1111C05, Passive Plus Inc., USA) was added to the main RF line to prevent DC signals from passing through the ports. Additionally, a decoupling capacitor was placed near the DC feed to ground any RF leakage.

The transmission coefficient (S21), representing insertion loss and isolation, was measured for both single switches in their on and off states across a frequency range of 100 MHZ to 500 MHz using a two-port vector network analyzer (e.g., FieldFox N9923A, Keysight Technologies, USA).

To evaluate the switching times for the RF switch 10 in FIG. 3 (at A), a signal generator (e.g., SMC100A, Rohde & Schwarz, Germany) with a continuous wave of 300 MHz and 0 dBm power level was connected in the input port. An oscilloscope (e.g., InfiniVision MSOX3104T, Keysight Technologies, USA) was connected to the other port and measured control circuit latency time, RF pulses, and their rising and falling times. The timing for the RF switch 10 was broken down into two components: mechanical latency and switching time. Electrical and mechanical latency time is defined as the time difference between user input to RF signal response of the RF switch 10. The switching time focuses specifically on the RF signal response change from 10% to 90% activation.

For high-power durability and temperature testing, a signal generator (e.g., SMC100A, Rohde & Schwarz, Germany) produced the RF source of a 500 MHz, 10 dBm signal, which was amplified to 100 W using a 40 dB gain amplifier (e.g., ZHL-100WGan+, Mini-Circuits, USA). The power line was connected to one of the single switch ports, and the other was terminated with a 50 Ω load (e.g., 100-T-FN, Bird, USA). Temperature measurements were conducted using an infrared camera (e.g., TrueIR U5855A, Keysight Technologies, USA). Experiments lasted 10 minutes, with temperature readings taken every minute. Additionally, an infrared image was captured at the 10th minute to document the temperature distribution of both switching systems.

### Evaluation of RF Switch Array

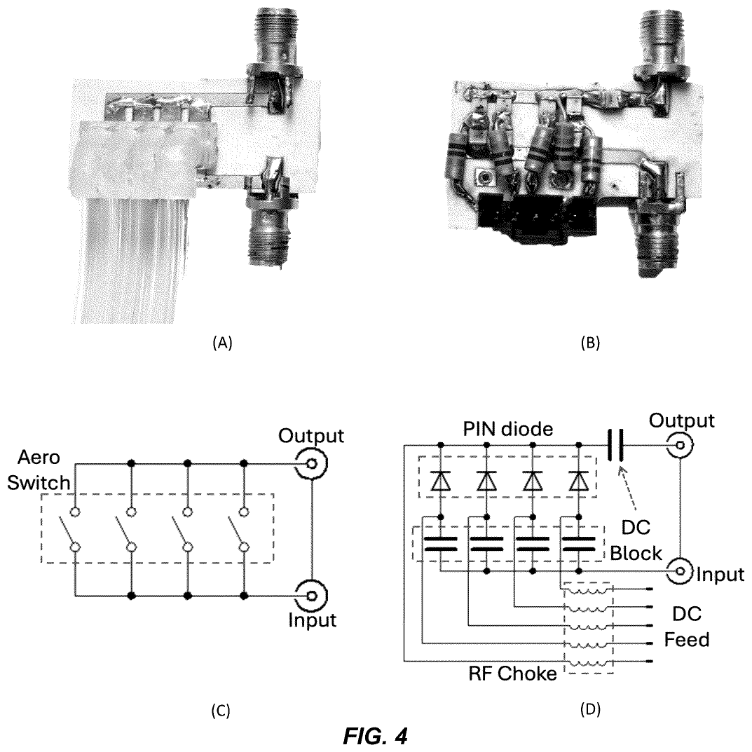

To assess the functionality and effects of combining individual RF switches 10 into a switching array, a four-RF switch array was built. In FIG. 4 (at A, C), the switches are connected in parallel on a PCB with two ports without any components in series with the switches. This ensured that the measured result would be the actual effect of the traces and the PCB geometry. Each switch was individually controlled by separate tubes linked to different channels of the air control station, enabling 16 possible switching combinations. A PIN diode switching array in FIG. 4 (at B) was constructed using a similar setup, incorporating the necessary biasing components with RF choke inductors and DC block capacitors with a similar value as described above. In this scenario, a DC block capacitor was connected in series with each PIN diode, but it was considered a very low impedance path because of its high capacitance. FIG. 4 (at D) illustrates the circuit diagram of all the connections between the components. The S21 parameters were measured across all 16 switching configurations for the RF switch array and the PIN diode switch array.

### L-Matching Circuit Testing

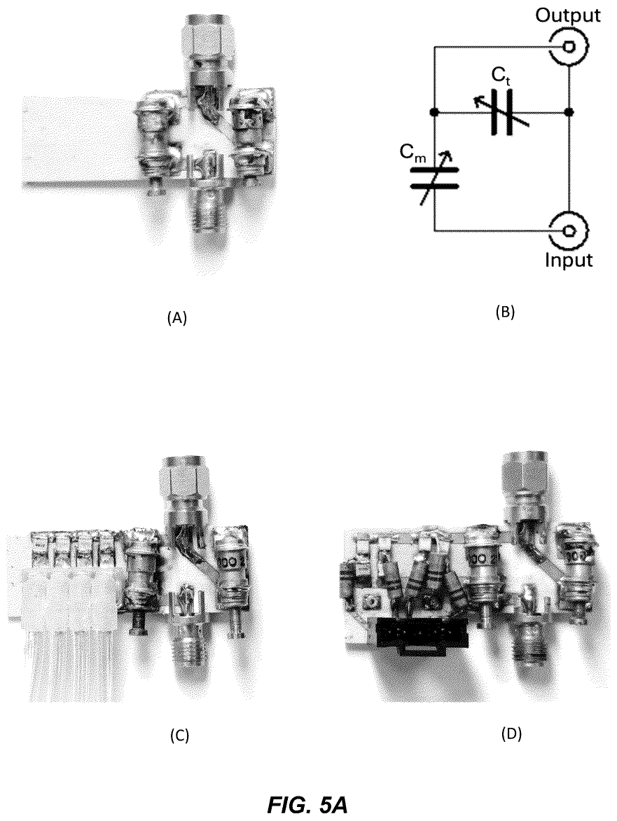

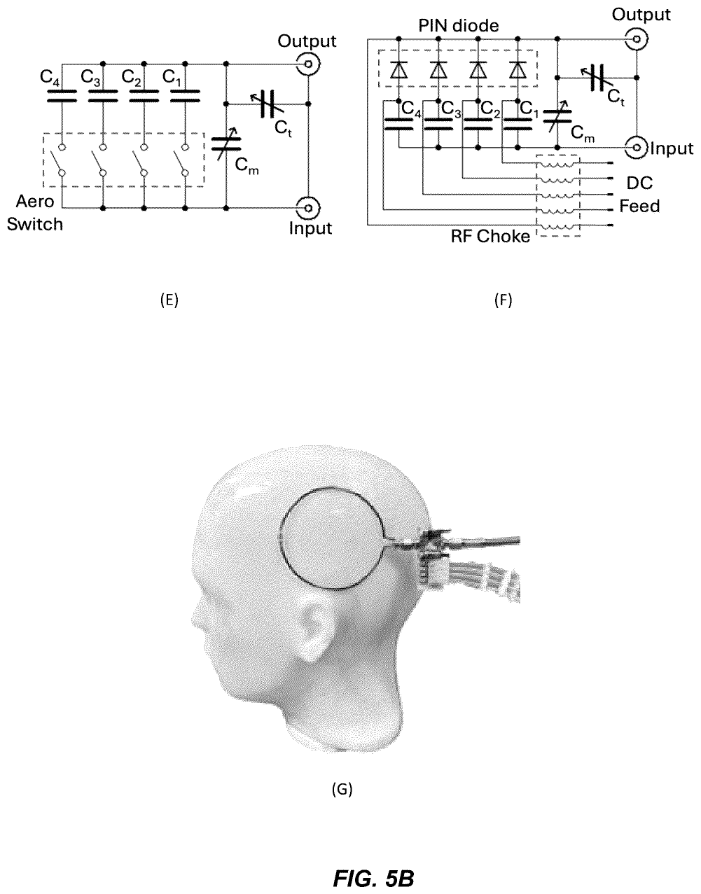

The switch arrays were then integrated into an L-type matching network. For the RF switch matching network as illustrated in FIG. 5A (at C) and FIG. 5B (at E), the circuit for the impedance matching included a serial capacitor switch array in parallel with a trimmer capacitor (e.g., V9000, Knowles Voltronics, USA) with the value Cm of approximately 6 pF. The capacitor switch array was made with the RF switch array, and each switch was serially connected to a lumped fixed-value capacitor (e.g., DKD1111C05, Passive Plus Inc., USA) with different values: C1=1.0, C2=1.2, C3=1.5, and C4=1.8 pF. When the switches were activated, their respective capacitances were added to the capacitance of a matching circuit, resulting in different matching conditions. A shunt trimmer capacitor with the value Ct approximately 10 pF was added as an impedance tuning capacitor of the matching network. A PIN diode switching array was used to construct an L-type matching network in the same configuration to the RF switch as shown in FIG. 5A (at D) and FIG. 5B (at F). DC block capacitors, RF choke inductors, and a DC feed connector were added to bias the PIN diodes, similar to arrangement described above. The matching networks have an input port for connecting to a source and an output port for connecting to a load.

A simple loop RF coil was designed to resonate at 298 MHz and used as a load. The coil was constructed using 80 mm diameter copper wire with a distributed capacitor of 2.7 pF at the center of a loop. The phantom used was a human head-shaped container, filled with a solution that had a permittivity of 68 and a conductivity of 0.54 S/m, representing the average electrical properties of the human brain. A basic L-type matching circuit in FIG. 5A (at A, B) without any capacitor switch array was also fabricated for control comparison. All three matching circuits were connected to the loop coil as a load, and the return loss (S₁₁) and input impedance were measured for both when the coil was loaded and unloaded with the phantom across all 16 switching configurations using a realistic MRI experimental setup, as shown in FIG. 5B (at G). The Q-factor was extracted from the Sun data using (1) where f_{c} is the central frequency and df is the −3 dB bandwidth of a resonance. The Q-factor determines the effect of the loss of the matching network

$$Q = {f}_{c} / {d}_{f} \qquad Eq . l$$

### Air Control System

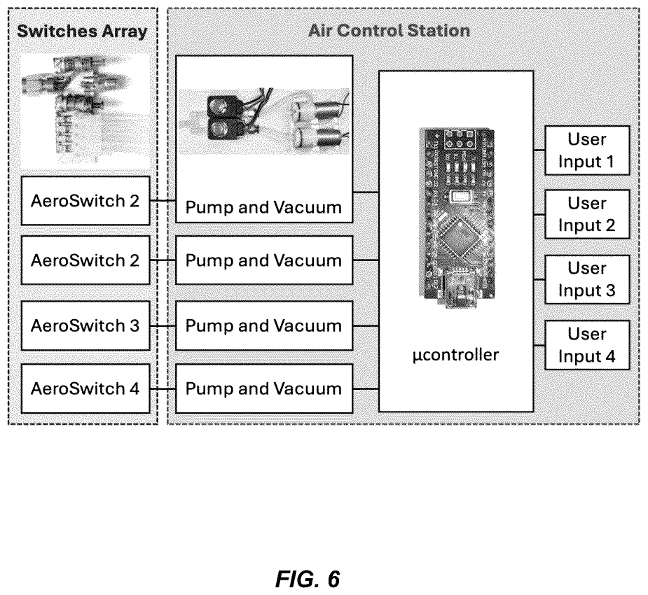

The air control system, shown in FIG. 6, was designed to supply adequate airflow through tubing to the RF switches 10 mounted on a switch array, enabling their independent activation and deactivation via pressure and vacuum, respectively. Each RF switch 10 is connected to a pair of directional mini air pumps within the same tube network. One pump supplies positive pressure to the network through its output connector, while the other generates negative pressure by connecting to the network via its suction connector. Since the pumps cannot maintain pressure on their own, each pump is paired with a normally closed solenoid valve (e.g., KL04000, Hangzhou Beduan Ecommerce Co., China), positioned between the pump and the network. As the valves and pumps activate simultaneously, each pump-valve pair is driven by a single MOSFET trigger switch drive module (e.g., ANMBEST, Wuhan, China). The MOSFET modules are electronically controlled by a microcontroller (e.g., Arduino Nano, Arduino, Italy), which reads user input from three-state switches configured in a pull-down setup. The system keeps all valves and pumps turned off when the user input switch is neutral. When switched to the second state, the positive pressure pump is activated, and its valve opens, allowing pressure to fill the tube and activate the RF switch 10. In the third state, the suction pump engages, opening its valve to create a vacuum in the tube, thereby deactivating the RF switch. Because the pump and vacuum unit is designed to control a single RF switch, four identical units were replicated to enable independent control of each switch.

### Results

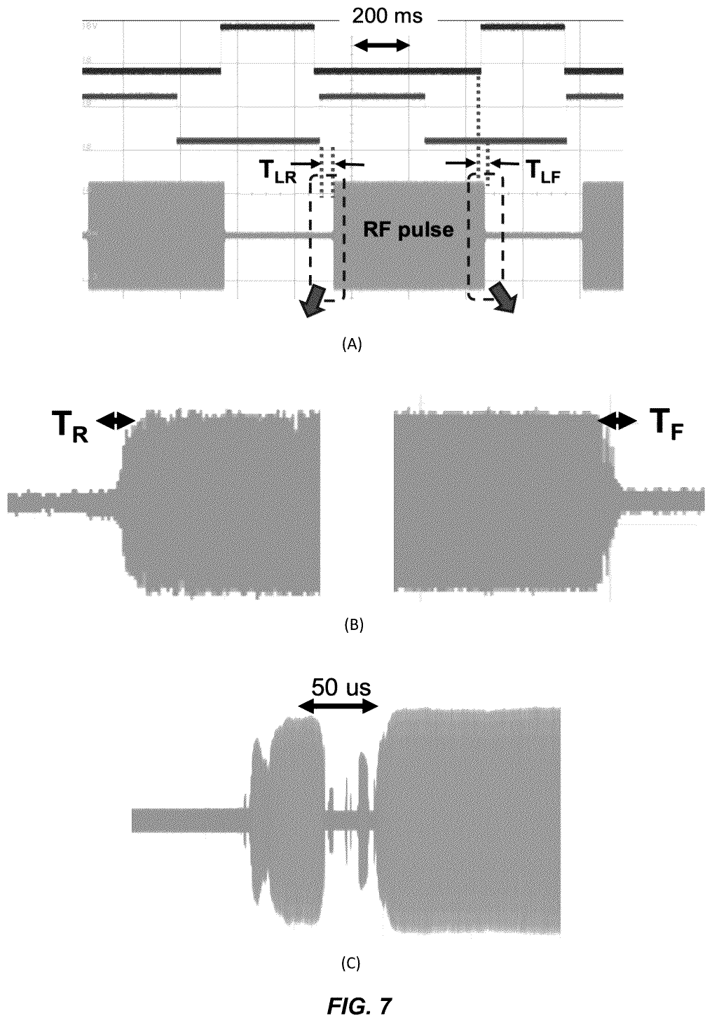

With respect to the single RF switch setups in FIG. 3, the switching time was measured from the user input signal at the air station to the activation of the conductive plunger using non-overlapped control signals to avoid a situation where pressure and vacuum occur simultaneously. In FIG. 7 (at A), the transition times for both rising (T_{LR}) and falling (T_{LF}) latency were approximately 40 ms. The switching time was measured within a range of ˜250 μs for both ON (T_{R}) and OFF (T_{F}) states as shown in FIG. 7 (at B). FIG. 6 (at C) shows the occasionally unstable switching caused by the bouncing of the contact when operated at excessively high pressure, even though it occurs inside the switching time range. In comparison, PIN diodes exhibit latency due to an electrical mechanism rather than mechanical properties and an average switching time of less than 200 ns. While the RF switch has slower switching times compared to PIN diodes, it is not a critical issue in applications that do not require nanosecond-range fast operation, such as control circuits for optimizing RF conditions.

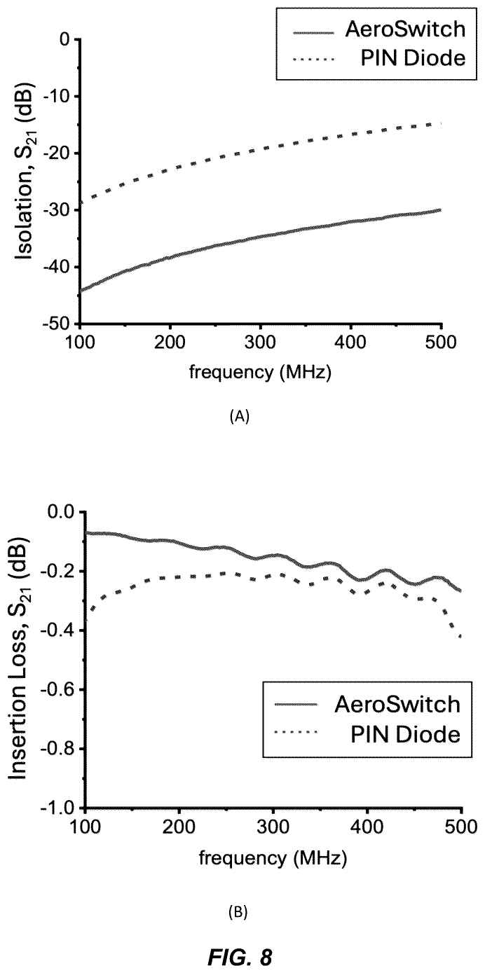

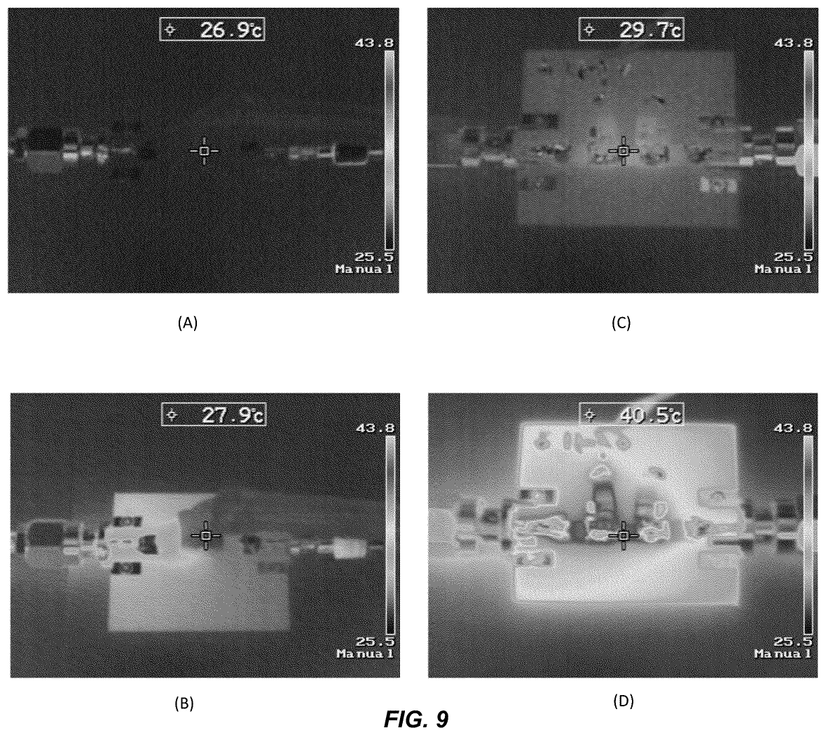

The measured average insertion loss of an RF Switch and a PIN diode from 100 MHZ to 500 MHz in FIG. 8 (at B) is −0.15 dB and −0.25 dB, respectively. Therefore, the RF Switch has an insertion loss of 0.1 dB higher than that of the PIN diode switch. The RF switch has an average isolation of −35 dB, while the PIN diode exhibits −20 dB. This indicates that the RF switch's isolation is 15 dB lower than that of the PIN diode switch, as illustrated in FIG. 8 (at A). These results suggest that more power can flow through the RF switch during the ON state, while less power can leak through the RF switch during the OFF state. This was expected because the RF switch is simply a conductor line, which should have very low resistance compared to the intrinsic resistance of the PIN diode. The measured data reflects the general frequency-dependent behavior of RF switches, driven by their intrinsic characteristics. As discussed above in the switching time analysis, the insertion loss and isolation are also determined by various factors. For example, a longer moving distance increases switching time and results in greater isolation.

The temperature measurement in FIG. 8. shows the PIN diode in the ON state reaches 29.7° C., only slightly higher than the RF switch at 26.9° C. However, when the switch remains in the OFF state for 10 minutes, the temperature of the PIN diode rises significantly to 40.5° C. due to the high RF power dissipation. In contrast, the RF switch exhibits only a minor temperature increase to 27.9° C., demonstrating superior thermal management. This difference suggests that the RF switch's airflow-assisted cooling effectively regulates its temperature, reducing the risk of overheating. Improved thermal stability, as observed in the RF switch, is particularly beneficial for RF applications such as MRI, where maintaining consistent performance over extended periods, typically at least 10 minutes per image acquisition, is important for minimizing signal distortion and ensuring compliance with safety regulations under high RF power levels, typically around 1 kilowatt to induce MR signals. The SNR in MRI can be defined as

$$SNR {∝}^{{B}_{1}} / \sqrt{{R}_{s} {T}_{s} + {R}_{c} {T}_{c}} \qquad ( 2 )$$

where B₁ is the induced RF magnetic field, R_{S} and R_{C} are the electrical resistance of the sample and coil, and T_{S} and T_{R} are their temperatures, respectively. The SNR is affected by the positive feedback loop between resistances (R_{S} and R_{C}) and temperatures (T_{S} and T_{C}). Specifically, an increase in temperature leads to a rise in resistances (e.g., for copper, resistance increases by approximately 0.4% per 1° C. temperature increase, and higher resistance, in turn, causes further temperature elevation. Alternatively, lowering T_{C} is essential for suppressing thermal noise, and improving the SNR.

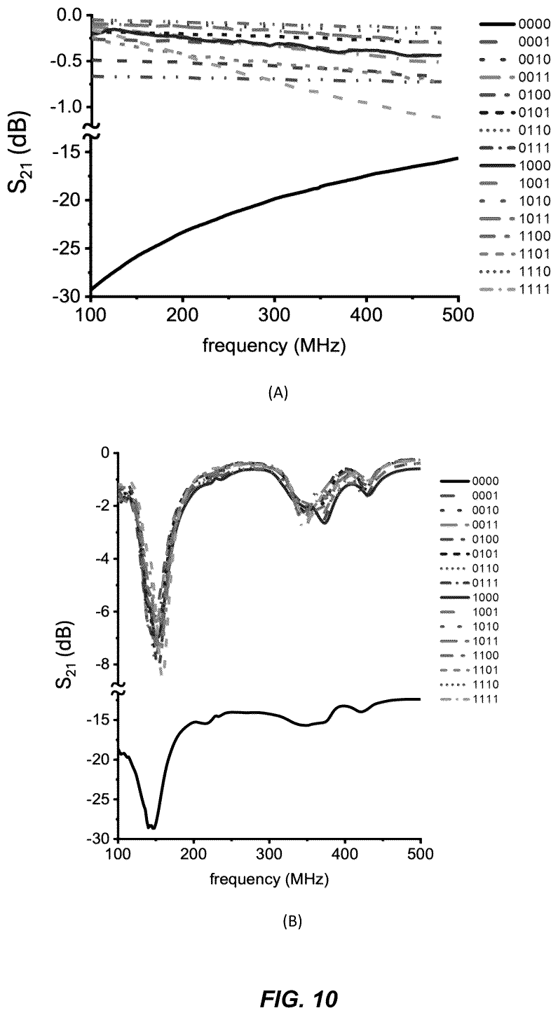

Next, the experiment analyzing the switching array configurations depicted in FIG. 4 was conducted. The S₂₁ measurement of the RF switch array shown in FIG. 10 (at A) revealed an isolation level below −15 dB across the entire frequency range when all switches remain deactivated, corresponding to the 0000 configuration. In contrast, an insertion loss exceeding-1.1 dB was noted for all other combinations (0001 to 1111). FIG. 10 (at B) presents the S₂₁ of the PIN diode switch array, exhibiting isolation below −12 dB, which is slightly underperformed than that of the RF switch array. Upon activation, the average insertion loss across all configurations was around −3 dB, lower than that of the RF switch array. The RF switch demonstrated superior isolation and insertion loss performance compared to the PIN diode, which was consistent with findings from the single switch experiment. However, the overall isolation level observed in this experiment was significantly higher than that of the signal switch experiment. This might be attributed to the capacitive coupling between the PCB's parallel traces rather than the switches themselves. Both the RF switch and PIN diode switch arrays featured parallel PCB traces. Thus, this effect is consistent in both setups without affecting the comparison of switch performance. The variations in insertion loss across switching configurations are minimal for both setups, indicating minimal influence from combining the switch into an array. Throughout the frequency range, the RF switch exhibited a linear S₂₁ response, while the PIN diode showed fluctuations with frequency. Furthermore, the broad bandwidth of testing complicates the maintenance of consistent behavior of the PIN diodes, including the bias circuit components, which change with frequency and may introduce additional attenuation at specific frequencies due to their parasitic characteristics.

After the performance of the RF switch array was validated, it was integrated into a matching network for a more practical experiment in FIG. 5B (at G) to evaluate the matching and tuning capability and the Q-factor.

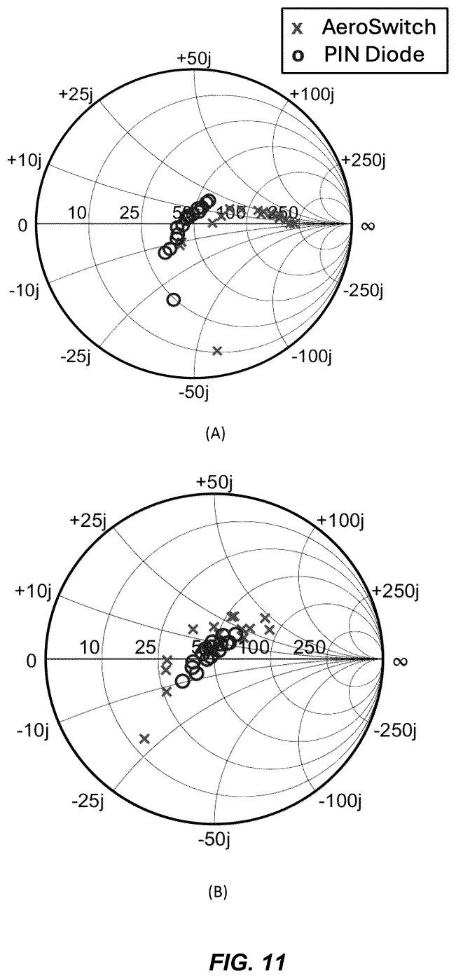

Without the matching network connected to the coil, the input impedance of the coil was measured to be at 32+j259.2 Ω at 300 MHz, which was highly mismatched from a 50 Ω system. With the matching network, the Smith charts display the measured input impedance by looking into the matching circuit for all setups across all 16 switching positions for both loaded and unloaded conditions in FIG. 11. As the switching positions transition from 0000 to 1111, the input impedance changes due to the addition of matching capacitance, which modified the matching conditions. This alteration caused the impedance points to move along an arc on the Smith chart. The trimmer capacitors were tuned so that the middle of the switching position matched the load to 50 Ω, which is the center of the Smith chart. The cluster size of impedance points showed a close similarity between the PIN diode and the RF switch matching network setups. The cluster was more spread out under the unloaded conditions in FIG. 11 (at A) compared to the loaded conditions in FIG. 11 (at B) because the coil is more sensitive to matching conditions when the loss from the load is present. This demonstrated the functionality of the matching network integrated with the RF switch.

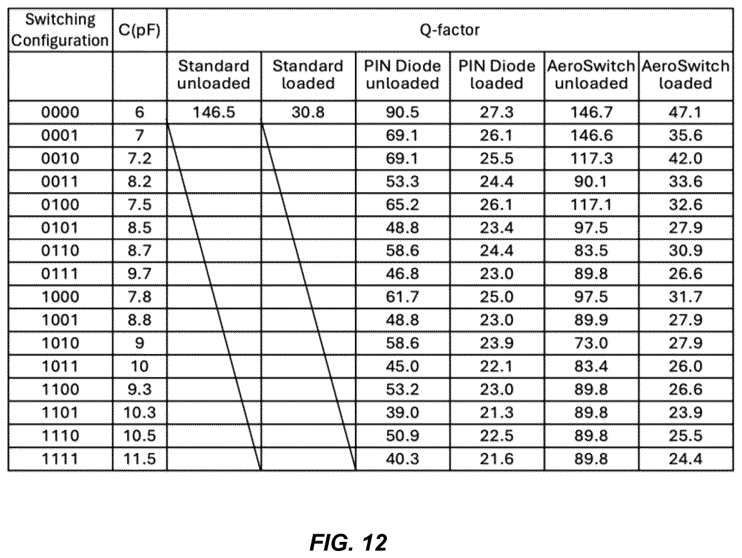

FIG. 12 lists the 16 switching configurations displayed as 0000 to 1111. Each digit corresponds to the activation of the four capacitors, where 0 indicates OFF and 1 indicates ON. Since the capacitors are connected in parallel, the summed capacitance of the activated capacitors, including the trimmer, is shown in the second column. Q-factors extracted from S₁₁ of the standard, PIN diode, and RF switch for both loaded and unloaded conditions are listed.

The Q-factor of the coil across all setups was derived from the measured S₁₁ data. The Q-factors for all setups are summarized in FIG. 12. The Q-factor of the standard setup in unloaded conditions exceeds 100, indicating that the coil and other components exhibit minimal loss and are optimal for this experiment. In unloaded conditions, the phantom's loss lowers the Q-factor to 30, and the Q-ratio, defined as Q-ratio=Q-unloaded/Q-loaded=3.33, illustrates that the coil is highly coupled with the phantom, which is beneficial for increasing signal sensitivity, leading to SNR improvement.

In comparing the RF switch and PIN diode setups under no load, the RF switch has an average Q-factor of 99.5, outperforming the PIN diode's Q-factor of 56.2. When loaded with the phantom, both setups see a reduced Q-factor. However, the RF switch's average Q-factor drops to 30.7, which is still higher than the 23.9 for PIN diodes. The combined average Q-factor for the RF switch in both loaded and unloaded states is 65.1, compared to 40 for the PIN diode. This indicates that the RF switch exceeds the PIN diode switch's average Q-factor by 62%. It's important to mention that when multiple switches are ON, the Q-factor significantly declines due to the increased capacitance observed in both setups under loading conditions.

The Q-factor comparisons between the two setups suggest that the PIN diode setup experiences higher losses than the RF switch setup, which aligns with findings from two prior experiments. This could be attributed to the RF switch's lower resistance than the intrinsic resistance of the PIN diode.

From the three experiments conducted, the mechanical switching tests demonstrated lower switching speeds compared to the PIN diode's electrical switching capabilities, making the RF switch more suitable for applications requiring lower switching speeds. The temperature testing revealed superior thermal regulation compared to the PIN diode, indicating its potential for high-power applications. Across all experiments, the RF switch exhibited lower insertion loss and higher isolation, making it well-suited for efficient power transmission. The Q-factor calculations in the matching network experiments highlighted differences in loss mechanisms, while Smith chart analysis provided insights into impedance variations, demonstrating the practical application of the RF switch for impedance matching. These findings offer a comprehensive comparison, showcasing the RF switch's advantages in minimizing power dissipation and improving efficiency for specific RF switching applications. One potential application is pre-clinical MRI, where SNR is a critical factor. The RF switch's ability to reduce losses makes it a promising candidate for such systems.

### Example—Rf Switch in MRI Application

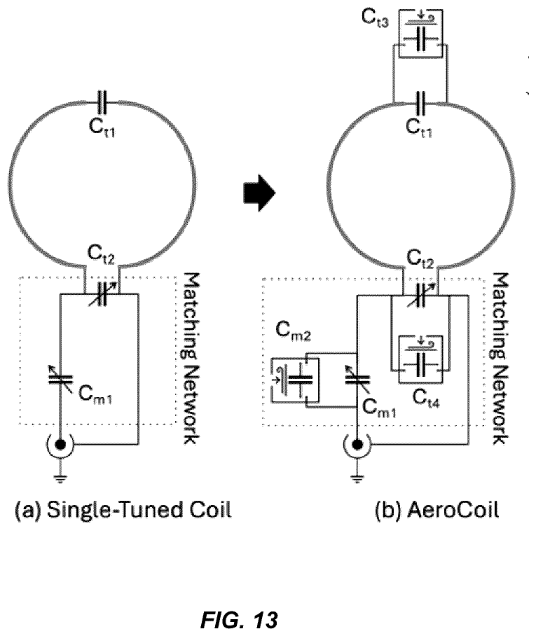

The RF switch 10 was incorporated with an RF coil of an MRI system (see FIG. 13) to compare bench testing and imaging performance with single-tuned coils for ¹H and ²H nuclei, respectively. The RF switch can be applied to optimize RF coils in various applications such as frequency switching, impedance matching, and decoupling. The RF switch can provide the potential to increase accessibility and time-effectiveness in clinical settings, where one coil could be used for multinuclear metabolic MRI without additional equipment or setup time. Furthermore, this capacitive tunable method, being MRI-compatible and non-magnetic, offers a non-electrical control approach that can be widely applied in MRI applications beyond RF coil design.

FIG. 13 (at (a)) illustrates a conventional RF coil. FIG. 13 (at (b)) illustrates an example arrangement of the RF switch 10 incorporated with a conventional RF coil. In the arrangement, the conventional RF coil is modified by adding one or more of the RF switches 10 in parallel with one or more fixed capacitors.

The RF coil is configured to enable resonance frequency switching through air pressure activation. In this example distilled water (H₂O) and heavy water (D₂O) were used as phantom samples for imaging due to their significant difference in Larmor frequencies, making it easier to demonstrate the RF coil's applicability to other nuclei. At 9.4T, the Larmor frequency is 400.2 MHz for proton (¹H) in H₂O and 61.4 MHz for deuterium (²H) in D₂O. Additionally, relevant frequencies for other nuclei include 376.5 MHz for fluorine (¹⁹F), 162 MHz for phosphorus (³¹P), 118 MHz for sodium (²³Na), and 100.6 MHz for carbon (13C).

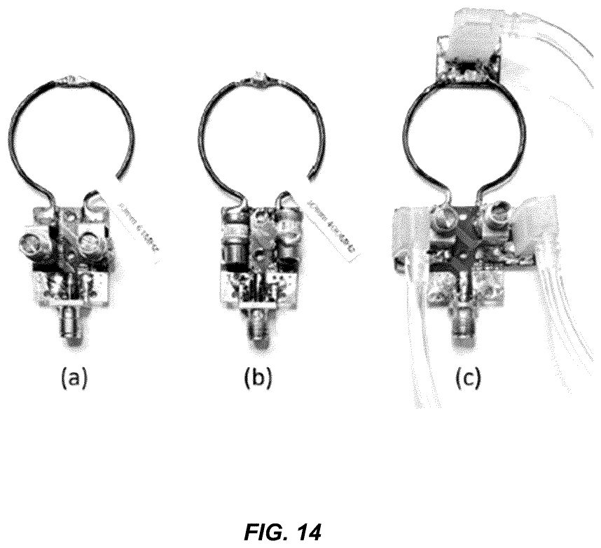

Two single-tuned coils were fabricated to resonate at 400.2 MHZ (FIG. 14 (at b)) and the other at 61.4 MHZ (FIG. 14 (at a)) to be used as the controlled coil. The coils are designed to enclose a phantom sample in the middle of the coil, resulting in a diameter of 30 mm. Each coil should have similar self-inductance and self-capacitance due to their similar geometry. Distributive capacitors (e.g., 1111C series, available from Passive Plus Inc. Huntington, New York, USA) with different values were added to alter the coil resonance frequency. An L-matching network was fabricated to match the coil impedance with the system's 50-ohm impedance at each frequency with two non-magnetic 5-25 pF trimmer capacitors (available from Sprague-Goodman, Westbury, New York, USA). The coils, loaded with a phantom position inside the bore, were finely matched and tuned manually to resonate at 61.4 MHz and 400.2 MHz with the scattering parameter (S₁₁) measured below −15 dB using a vector network analyzer (available from, for example, FieldFox N9923A, Keysight Technologies, USA).

The RF coil was fabricated by adding the RF switch 10 parallel to the 400.2 MHZ single-tuned coil capacitors. When the RF switches 10 were activated, a large amount of capacitance was added to the distributive and matching circuit capacitances, resulting in a significant shift of the resonance frequency to 61 MHz. The fabricated coil is shown in FIG. 14 (at (c)). All capacitance values used for each coil are specified in Table 1 with the variables referred to from the coil diagram in FIG. 13. Since the trimmer capacitors are used for fine matching and tuning circuits, the values of Cₜ₂ and Cₘ₁ in the table are estimated. All other capacitors are fixed-value capacitors with the value provided by the manufacturer. The Cₜ₄ capacitance of 105.6 pF was achieved by stacking a fixed value 100 pF and a 5.6 pF capacitor inside the RF switch. The coils were manually matched and tuned slightly using the trimmer capacitors, similar to standard coil settings, to compensate for the loading effect from the sample and the scanner bore coupling.

TABLE 1

| | Cₜ₁ | Cₜ₂ | Cₘ₁ | Cₜ₃ | Cₜ₄ | Cₘ₂ |
|---|---|---|---|---|---|---|
| Single-Tuned Coil 61.4 MHz | 300 pF | 20 pF | 10 pF | — | — | — |
| Single-Tuned Coil 400.2 MHz | 2.2 pF | 20 pF | 9 pF | — | — | — |
| AeroCoil | 2.2 pF | 20 pF | 10 pF | 300 pF | 105.6 pF | 1 pF |

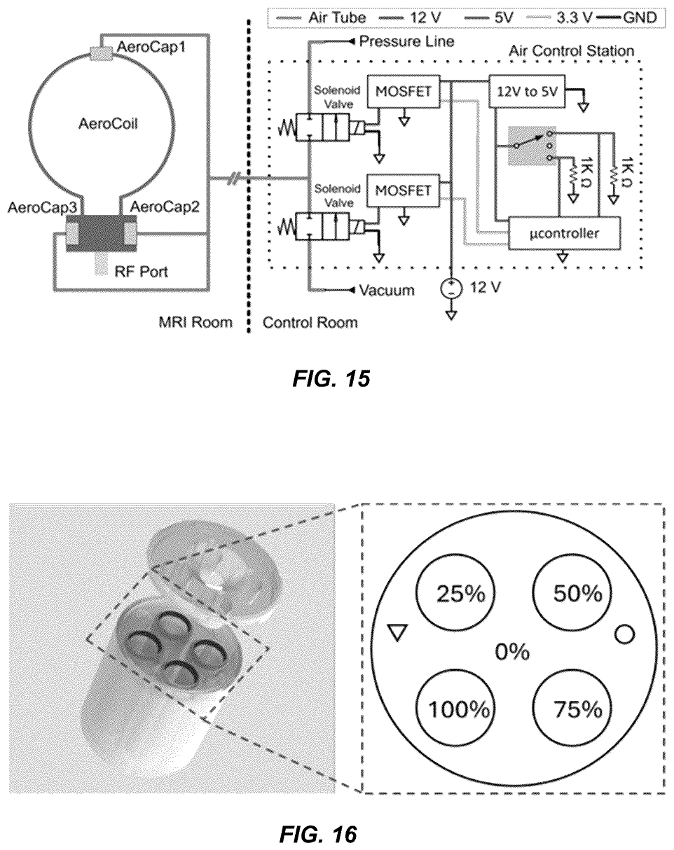

During a scan session, the RF switches located in the scanner bore were connected to the same air tube so that they could be engaged simultaneously by an air control station located in the control room. The diagram of the pneumatic system is shown in FIG. 15. The air control station included two 12 V solenoid valves (e.g., k104000 available from Hangzhou Beduan E-commerce Co., China), one connected to a pressure line and the other to a vacuum line equipped in the building facility. The pressure line provides high pressure, which PSI regulates. The other end of the valves was connected to the same long air tube leading to the RF switch. The valves were driven by MOSFET trigger switch drive modules (available from, for example, ANMBEST, Wuhan, China), controlled electronically by a microcontroller (available from, for example, Arduino Nano, Arduino, Italy). A 12 V DC power supply (e.g., U8032A available from Keysight Technologies, USA) provides power for the valves and gets regulated to 5 V for the microcontroller via the 12 V to 5 V DC convertor (e.g., B093VB61Y6 available from ACEIRMC). The microcontroller read the input from a user-controlled three-state switch in the pull-down configuration, corresponding to three control states. First, the neutral state closes all the valves, blocking the connection between the coil and the air lines. Second, the engaged state opens the pressure line connection to pressurize the air tube system and engage the RF switch while closing the vacuum line. In this state, the coil resonated at 61.4 MHZ. In the disengaged state, the pressure line was closed, and the vacuum line was opened, allowing negative pressure inside the air tube and disengaging the RF switch, which changed the coil resonance to 400.2 MHz.

With reference to FIG. 16, a 3D-printed phantom container was configured as a cylinder having approximate dimensions of 30 mm in height and 25 mm in diameter. The container includes four cylindrical wells holding approximately 0.6 ml, with a surrounding outer compartment holding about 5 ml. This layout allowed for easy comparison of samples of different concentrations or compositions. A small triangular and circular pillar in the phantom allowed for easy identification of the sample orientation in MR images.

The four phantom wells were filled with D₂O diluted in H₂O with concentrations of 13.75 M, 27.5 M, 41.75 M, and 55 M, representing 25%, 50%, 75%, and 100% of the molar concentration of pure D₂O. The outer compartment of the phantom was also filled with the unaltered deionized H₂O, which has a natural abundance 2H concentration of approximately 10 mM, which is equivalent to 5 mM D₂O.

### Results

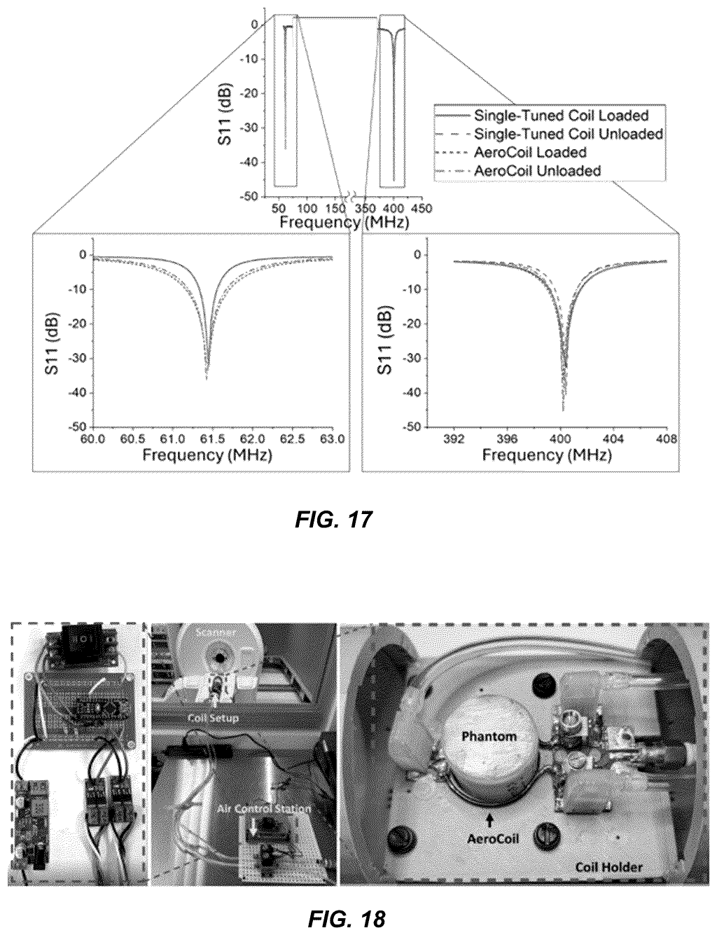

The coils were tested on a bench with a vector network analyzer to measure a scattering parameter of S₁₁. Comparisons were made between the single-tuned standard coils and RF coil with RF switch 10 at 61.4 MHz and 400.2 MHz with loaded and unloaded conditions. The phantom mentioned above was used for the loaded condition. FIG. 17 shows the measured S₁₁ at 61.4 and 400.2 MHz for the single-tuned standard coils and the RF coil with RF switch 10 for both loading conditions. From the plots, each coil resonated precisely at the designed frequencies below −30 dB.

The Q factor of each coil for each condition was measured from the −3 dB bandwidth. Table 2 shows all the measured Q values. The ratio between Q unloaded and Q loaded is the coil's Q ratio. For 400.2 MHz, AeroCoil has a Q ratio of 1.246, comparable to the single-tuned standard coil of 1.412. For 61.4 MHz, AeroCoil has a Q ratio of 1.159 compared to the single-tuned standard coil of 1.002.

TABLE 2

| | Q Loaded | Q Unloaded | Q Ratio |
|---|---|---|---|
| Single-Tuned Coil 61.4 MHz | 97.48 | 97.7 | 1.002 |
| AeroCoil 61.4 MHz | 40.98 | 47.5 | 1.159 |
| Single-Tuned Coil 400.2 MHz | 63.89 | 90.2 | 1.412 |
| AeroCoil 400.2 MHz | 61.67 | 76.85 | 1.246 |

### Imaging Results

Ultrahigh field 9.4T MR imaging was conducted to validate the performance of the RF coil with RF switch 10 using a 17 cm horizontal-bore dry magnet MRI scanner (available from MR Solutions, Guildford UK, Europe) at the KE Biosciences Preclinical Imaging Center, Arizona State University.

Coil holder structures were 3D printed to fix the coils and phantom inside the bore to minimize the motion artifact from mechanical vibration. Each coil was fixed on each stabilizer with a phantom inserted in the middle of the coil before fixing the holder on the animal bed. The coils were then inserted in the bore, well-matched, and tuned to resonate at 400.2 MHz for ¹H imaging and 61.4 MHz for ²H imaging, with S₁₁ below −15 dB. FIG. 18 shows the coil setup in the scanning room and the air station setup in the control room. The air station is the implementation of the diagram in FIG. 15.

The imaging sequence used was Fast-Low-Angle-Shot (FLASH) T1-weighted gradient echo. The imaging parameters were set to a repetition time (T_{R}) of 60 ms, an echo time (TE) of 4 ms, and a flip angle (a) of 35°. The field-of-view (FOV) was set to 60×60 mm with a matrix size of 256×256 and a slice thickness of 4 mm. Another sequence used is Fast-Spin-Echo T2 weighted (FSE T2w) with a T_{R} of 5000 ms and a TE of 39 ms. FOV was set to 100×100 mm with a matrix size of 238×256 and a slice thickness of 4 mm. The imaging sessions were repeated two times.

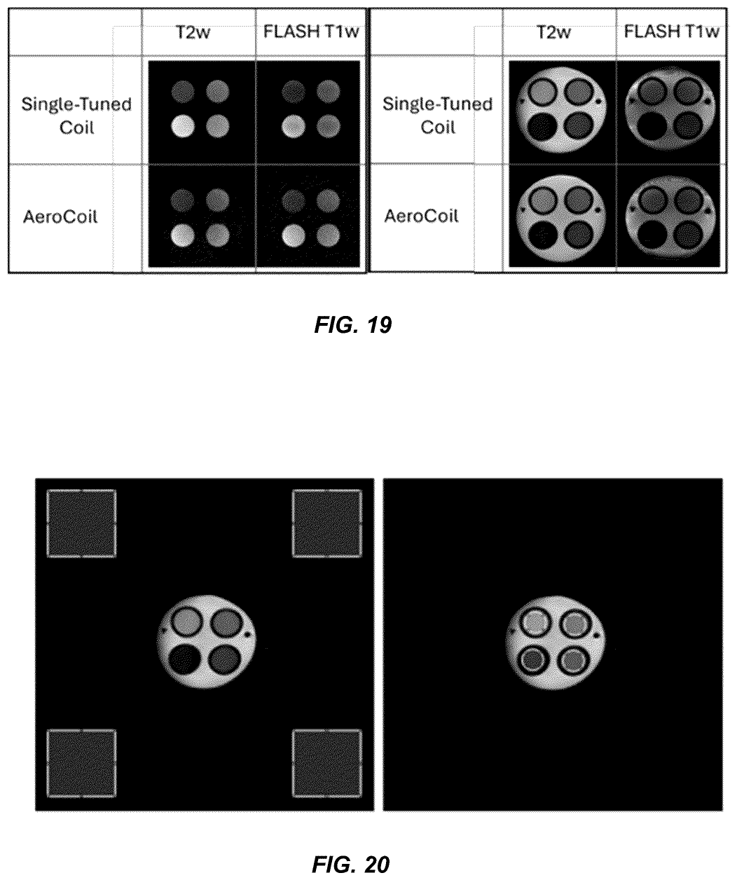

FIG. 19 shows raw images from the scanning. For ¹H imaging, the intensity of each circle inversely corresponds to the concentration of the D₂O, as expected. The outer part of the phantom has the highest intensity because it is H₂O. For ²H imaging, the intensity of the circles is proportional to the concentration of the D₂O.

The SNR in each circle from each image was calculated with MATLAB (available from, for example, Math Works, MA, USA). Four regions of interest (ROI) of each circle were defined to measure the mean intensity. Another four square ROIs from four background corners were measured for standard deviation. The ROIs are shown in FIG. 20.

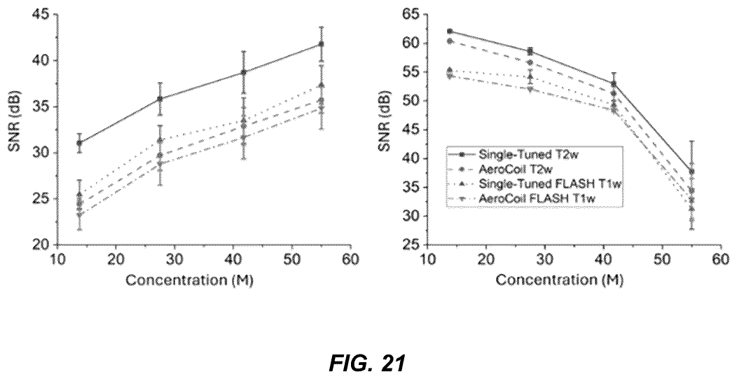

FIG. 21 (left) shows the SNR plot in dB of MR images at 61 MHz. It indicates that the ROI's SNR increases with the concentration of D₂O, as expected since this is its Larmor frequency.

Compared to the single-tuned coil, the RF coil with RF switch SNR decreased on average by 7.22% for the FLASH T1-weighted sequence and 16.8% for the T2-weighted sequence. FIG. 21 (right) shows the SNR in dB of ROIs at 400.2 MHz. The SNR decreased as the D₂O concentration increased due to the corresponding decrease in H₂O concentration. The mean SNR reduction for the RF coil with RF switch compared to the single-tuned coil is 2.83% for the FLASH T1-weighted sequence and 4.02% for the T2-weighted sequence.

### DISCUSSION

In bench testing, the Q-factors of the RF coil with RF switch for both loading conditions and frequencies were lower than those of the single-tuned coils. This result was expected since the single-tuned coils were optimized for their designed frequency and generally outperformed the dual-tuned coils. However, the RF switches on the RF coil could potentially introduce electrical resistance at the contact surfaces, which would be added to the coil circuit. An increase in coil resistance directly lead to a decrease in the Q-factor, as per the equation:

$$Q = \frac{ω L}{R} \qquad ( 3 )$$

Q is the Q-factor, ω is the resonance frequency, L is the inductance and R is the resistance.

Certain conductor traces might also introduce parasitic inductance to the coil, which could degrade the Q-factor.

This equation defines the Q ratio:

$${Q}_{rario} = \frac{{Q}_{u n l o a d e d}}{{Q}_{l o a d e d}} = \frac{{R}_{c} + {R}_{s}}{{R}_{c}} \qquad ( 4 )$$

Qᵣₐₜᵢₒ is the unitless Q ratio of the coil, Q_{unloaded} is the Q-factor of the coil in unloaded condition, Q_{loaded} is the Q-factor of the coil in the loaded condition, R_{c} is the resistance of the coil, and R_{S} is the resistance of the sample.

The Q ratios of the RF coil with RF switch and the single-tuned coils at both frequencies were comparable, although slightly lower for the RF coil with RF switch. This suggested that the RF coil with RF switch may have slightly less sensitivity than the single-tuned coils. Additionally, all the coils have Q ratios of less than 2, indicating that the coil's resistance dominates the sample. One possible explanation could be that the phantom size is relatively smaller than the coil.

In the resulting images, the observed artifacts in the FLASH T1-weighted gradient echo sequence may be attributed to fluid motion induced by mechanical vibration or non-uniformity in the magnetic field. However, the consistent artifact pattern observed in both the RF coil with RF switch and single-tuned coils suggested that the artifacts likely stem from the experimental setup rather than the coils.

The SNR of the RF coil with RF switch was also expected to be slightly lower since it is proportional to the resistance of the coil as described by equation 2. The sensitivity of the coil to the signal decreases with higher resistance, increasing noise susceptibility. The activation of the RF switch at 61.4 MHz causes the most significant SNR loss, indicating that the loss of the RF switch contact point is the primary issue, as discussed. The housing of the RF switch is 3D printed with resin, which makes the sliding mechanism less than ideal and might prevent full connection at the contact points. The resin also has low resistance to heat, which hampers proper soldering of the coil. Further investigation into the sophisticated fabrication and materials of RF switch could decrease contact resistance, potentially improving the performance of RF coil with RF switch.

The target nuclei in this example, ¹H, and ²H, have very different Larmor frequencies of 338.8 MHz, which is an extreme scenario for a dual-tuned coil. Tuning and matching to achieve the appropriate matching conditions for both frequencies between these two frequencies are also challenging to optimize. As a result, this might also affect the measured Q-factor and SNR. With nuclei with Larmor frequency near ¹H, the matching and tuning would be less complex and might result in better SNR. Since it was demonstrated that the capability of switching between 400.2 and 61.4 MHz, nuclei that fall in this frequency range could be easily implemented.

Additional features and advantages of the present disclosure are set forth in the following claims.

What is claimed is:

1. A radio-frequency (RF) switch comprising:
a housing defining an interior volume, the housing including a first end and a second end, the first end including a port in fluid communication with an air pressure source, the second end including a plurality of pads in electrical communication with components on a circuit board; and
a block positioned within the housing and extending a width of an interior surface of the housing, the block configured to move along an axis, the block including a lower portion having an electrically conductive material;
wherein the RF switch is activated when the lower portion of the block moves along the axis to be in contact with the plurality of pads due to pressurization of the interior volume, and
wherein the RF switch is deactivated when the lower portion of the block moves along the axis to not be in contact with the plurality of pads due to depressurization of the interior volume.

2. The RF switch of claim 1, further comprising a first leg and a second leg extending from the plurality of pads into the interior volume of the housing, and wherein the lower portion of the block removably contacts the first leg and the second leg.

3. The RF switch of claim 2, wherein the first leg and the second leg include an electrically conductive material.

4. A system comprising:
an RF coil or a circuit; and
a plurality of pneumatically switchable circuit components in selective electrical communication with the RF coil or the circuit, the plurality of pneumatically switchable circuit components in communication with an air pressure source or a vacuum source to adjust one of a capacitance, an inductance, or a resistance of the pneumatically switchable circuit components.

5. The system of claim 4, wherein the plurality of pneumatically switchable circuit components includes one or more of a capacitor, an inductor, a resistor, and a signal pathway switch.

6. The system of claim 4, wherein the plurality of pneumatically switchable circuit components are oriented in parallel with a plurality of fixed circuit components.

7. The system of claim 4, wherein one of the plurality of pneumatically switchable circuit components comprises
a housing in communication with the air pressure source or the vacuum source,
a first connector coupled to the housing and configured to move within the housing, and
a second connector electrically coupled to the RF coil or the circuit, the second connector defining a recess configured to selectively receive the first connector,
wherein the first connector is received within the recess when a sufficient amount of air pressure is applied to the housing, and
wherein the first connector is not in contact with the second connector when a vacuum is applied to the housing.

8. The system of claim 7, wherein the one of the pneumatically switchable circuit components is activated when the first connector is engaged with the second connector thereby generating an electrical connection.

9. The system of claim 7, wherein the one of the pneumatically switchable circuit components is deactivated when the first connector is disengaged with the second connector.

10. The system of claim 4, wherein the plurality of pneumatically switchable circuit components are configured to control a resonating property of the RF coil.

11. The system of claim 10, wherein the resonating property is frequency.

12. A method comprising:
positioning a pneumatically-controlled switchable circuit in electrical communication with a fixed circuit component; and
controlling the pneumatically-controlled switchable circuit to optimize radio-frequency (RF) conditions of a RF coil by applying air pressure or vacuum to the pneumatically-controlled switchable circuit.

13. The method of claim 12, wherein the RF conditions are frequency, impedance matching, and RF decoupling.

14. The method of claim 12, wherein the RF coil is in a magnetic resonance imaging device.

15. The method of claim 14, wherein controlling the pneumatically-controlled switchable circuit is performed in real-time to optimize the RF conditions of the RF coil during an MRI procedure.

16. A system for magnetic resonance imaging (MRI) or magnetic resonance spectroscopy, the system comprising:
a radiofrequency (RF) coil; and
a pneumatic control system electrically coupled to an MRI scanner, the pneumatic control system including
a plurality of pneumatically switchable circuit components in selective electrical communication with the RF coil, the plurality of pneumatically switchable circuit components in communication with an air pressure source or a vacuum source to optimize RF conditions of the RF coil;
wherein the pneumatic control system is configured to adjust one of the RF conditions of the RF coil by adjusting one or more of the plurality of pneumatically switchable circuit components to match a target nucleus being measured before a pulse sequence for each nucleus based on a gating signal received from the MRI scanner.

17. The system of claim 16, wherein one of the plurality of pneumatically switchable circuit components is a capacitor.

18. The system of claim 17, wherein one of the RF conditions is resonant frequency.

19. The system of claim 18, wherein the pneumatic control system is configured to adjust one of the RF conditions of the RF coil in real-time.

20. The system of claim 18, wherein the pneumatic control system is configured to adjust one of the RF conditions based on a predetermined pulse sequence for each nucleus.
